(19) United States
(12) Patent Application Publication
(10) Pub. No.: US 2025/0200138 A1
(43) Pub. Date: Jun. 19, 2025

(54) ACCELERATOR FOR OPERATIONS BETWEEN FLOATING POINT MATRIX AND INTEGER MATRIX AND OPERATION METHOD THEREOF

(71) Applicant: SEOUL NATIONAL UNIVERSITY R&DB FOUNDATION, Seoul (KR)

(72) Inventors: Jae-Joon KIM, Seoul (KR); Jaeyong JANG, Seoul (KR); Yulhwa KIM, Seoul (KR)

(21) Appl. No.: 18/984,464

(22) Filed: Dec. 17, 2024

(30) Foreign Application Priority Data
Dec. 19, 2023 (KR) 10-2023-0185522
Apr. 19, 2024 (KR) 10-2024-0052471

(51) Int. Cl. G06F 17/16; H03M 7/24

(52) U.S. Cl. CPC G06F 17/16; H03M 7/24

(57) ABSTRACT

An operation accelerator that performs an operation between a floating point matrix and an integer matrix includes a first buffer storing integer matrix data; a second buffer storing floating point matrix data; a data converter to convert the floating point matrix data into an integer; and an operator to perform multiplication on the integer matrix data and integer operation target matrix data output from the data converter, wherein the data converter includes a pre-aligner to find a maximum exponent value among multiple floating point values included in the floating point matrix data, perform pre-alignment for moving a mantissa of each of floating points by a difference between the maximum exponent value and an exponent value of each of the multiple floating point values, and generate the integer operation target matrix data based on mantissas of a preset number of high-order bits extracted from among mantissas of pre-aligned floating point values.

### CROSS-REFERENCE TO RELATED APPLICATION

This application claims the benefit under 35 USC 119(a) of Korean Patent Application Nos. 10-2024-0052471 filed on Apr. 19, 2024 and 10-2023-0185522 filed on Dec. 19, 2023 in the Korean Intellectual Property Office, the entire disclosures of which are incorporated herein by reference for all purposes.

### BACKGROUND

### 1. Field

The present disclosure relates to an operation accelerator that processes operations between floating-point matrices and integer matrices and an operation method thereof.

### 2. Description of the Related Art

Large language models (LLMs) demonstrate human-level problem-solving ability in the field of natural language processing, thereby being actively studied. In particular, research on lightweight techniques and accelerator devices for operating the large language models at low cost is increasing.

Among various lightweight techniques, the technique for reducing memory usage by quantizing synapse weights into integers and maintaining neuron values as floating points is evaluated as having high commercialization potential. In this way, operations between neuron-synapse weights, which are the core of large language model operations, consist of operations between floating-point matrices and integer matrices, but previously developed operators are designed to process only single-format data operations, such as operations between integers or operations between floating-points. Therefore, in the conventional systems, operations between floating-point matrices and integer matrices are processed by a floating-point operator.

The present disclosure proposes an operation accelerator that enables operations between floating-point matrices and integer matrices to be performed by an integer operator in order to drive multiplication between the floating-point matrices and the integer matrices at low cost.

The patent document related thereto includes Korean Patent Publication No. 2023-0094627 (Title of the Invention: APPARATUS AND METHOD FOR COMPUTING FLOATING POINT BY IN-MEMORY COMPUTING).

### SUMMARY

The present disclosure provides an operation accelerator that may perform an operation between a floating-point matrix and an integer matrix and an operation method of the operation accelerator.

However, technical objects to be achieved by the present embodiments are not limited to the technical objects described above, and other technical objects may exist.

According to an aspect of the present disclosure, an operation accelerator that performs an operation between a floating point matrix and an integer matrix includes a first buffer storing integer matrix data; a second buffer storing floating point matrix data; a data converter configured to convert the floating point matrix data into an integer; and an operator configured to perform multiplication on the integer matrix data and integer operation target matrix data output from the data converter, wherein the data converter includes a pre-aligner configured to find a maximum exponent value among multiple floating point values included in the floating point matrix data, perform pre-alignment for moving a mantissa of each of floating points by a difference between the maximum exponent value and an exponent value of each of the multiple floating point values, and generate the integer operation target matrix data based on mantissas of a preset number of high-order bits extracted from among mantissas of pre-aligned floating point values.

According to another aspect of the present disclosure, an operation method for processing an operation between a floating-point matrix and an integer matrix by using an operation accelerator includes inputting integer matrix data and floating point matrix data; outputting integer operation target matrix data by converting the floating point matrix data into integers; and performing multiplication by transferring the integer matrix data and the integer operation target matrix data to an operator, wherein the outputting of the integer operation target matrix data includes finding a maximum exponent value among multiple floating point values included in the floating point matrix data, performing pre-alignment for moving a mantissa of each of floating points by a difference between the maximum exponent value and an exponent value of each of the multiple floating point values, and generating the integer operation target matrix data based on mantissas of a preset number of high-order bits extracted from among mantissas of pre-aligned floating point values.

According to the present disclosure, multiplication between a floating-point value and an integer value may be performed by using an integer operator. Accordingly, an operation between floating-point-based activation and an integer-based weight may be efficiently performed by a large language model or so on.

In addition, by performing an additional operation, such as truncating some bits after floating-point mantissa alignment or allocating a chunk to valid bits, the number of registers required for configuring an operation accelerator may be reduced, and thus, an area and energy efficiency of the operation accelerator may be increased.

### BRIEF DESCRIPTION OF THE DRAWINGS

FIG. 1 illustrates an operation accelerator according to an embodiment of the present disclosure.

FIGS. 2A, 2B and 3 are diagrams illustrating a pre-alignment process of floating-points, according to embodiments of the present disclosure.

FIG. 4 illustrates a logic of a pre-aligner according to an embodiment of the present disclosure.

FIGS. 5A, 5B, 5C and 5D illustrate diagrams of operations of a chunk allocator according to an embodiment of the present disclosure.

FIG. 6 illustrates a logic of a chunk allocator according to an embodiment of the present disclosure.

FIG. 7 is a flowchart illustrating an operation method according to an embodiment of the present disclosure.

### DETAILED DESCRIPTION

Hereinafter, embodiments of the present disclosure will be described in detail with reference to the attached drawings such that those skilled in the art to which the present disclosure belongs may easily practice the present disclosure. However, the present disclosure may be implemented in various different forms and is not limited to the embodiments described herein. In addition, in order to clearly describe the present disclosure in the drawings, parts that are not related to the description are omitted, and similar components are given similar reference numerals throughout the specification.

In the entire specification of the present disclosure, when a component is described to be “connected” to another component, this includes not only a case where the component is “directly connected” to another component but also a case where the component is “electrically connected” to another component with another element therebetween. In addition, when it is described that a portion “includes” a certain component, this means that the portion may further include another component without excluding another component unless otherwise stated.

In the present disclosure, a “portion” includes a unit realized by hardware, a unit realized by software, and a unit realized by using both. In addition, one unit may be realized by using two or more pieces of hardware, and two or more units may be realized by using one piece of hardware. Meanwhile, a “˜portion” is not limited to software or hardware, and a “˜portion” may be configured to be included in an addressable storage medium or may be configured to reproduce one or more processors. Therefore, in one example, “˜portion” refers to components, such as software components, object-oriented software components, class components, and task components, and includes processes, functions, properties, and procedures, subroutines, segments of program code, drivers, firmware, microcode, circuits, data, databases, data structures, tables, arrays, and variables. The functions provided within the components and “portions” may be combined into a smaller number of components and “portions” or may be further separated into additional components and “portions”. Additionally, components and “portions” may be implemented to regenerate one or more central processing units (CPUs) included in a device or security multimedia card.

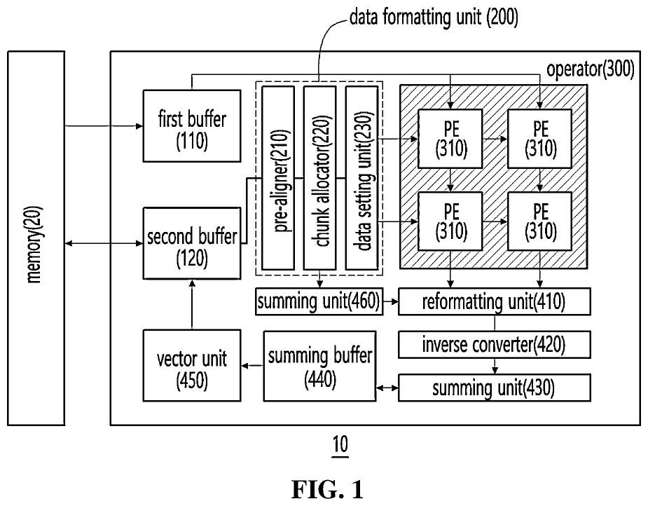

FIG. 1 illustrates an operation accelerator according to an embodiment of the present disclosure.

An operation accelerator 10 includes a first buffer 110 in which integer matrix data received from a memory 20 is stored, a second buffer 120 in which floating point matrix data received from the memory 20 is stored, a data converter 200 that converts the floating point matrix data into integers; and an operator 300 that performs a matrix operation on integer matrix data and the converted integer matrix data output by the data converter 200. In addition, the operation accelerator 10 may further include a reformatting unit 410, an inverse converter 420, a summing unit 430, a summing buffer 440, and a vector unit 450.

The first buffer 110 stores integer matrix data. Integer data included in the integer matrix data may indicate a weight multiplied by an activation value output from a previous layer in each layer that constitutes a learning model based on a deep neural network, or a weight in a perceptron that simulates a neuron.

The second buffer 120 stores floating point matrix data. The floating point matrix data may indicate an activation value output from each layer that constitutes the learning model based on the deep neural network. In addition, the second buffer 120 temporarily stores output data according to an operation of the integer matrix data and the floating point matrix data, and outputs the temporarily stored data to the memory 20. For example, a result of multiplication of a weight and an activation may be temporarily stored.

The data converter 200 converts the floating point matrix data into an integer. To this end, the data converter 200 may include a pre-aligner 210, a chunk allocator 220, and a data setting unit 230. The data converter 200 finds the maximum exponent among a plurality of floating-point values included in the floating point matrix data, performs pre-alignment for moving a mantissa of each floating-point value by a difference between the maximum exponent and the exponent of each floating-point value, and generates integer matrix data based on the mantissa extracted by truncating a preset number of high-order bits from mantissas of respective pre-aligned floating-point values. More specific details of the operation will be described in detail below.

The operator 300 may include multiple processing elements (PEs) 310 that operate on the integer matrix data received from the first buffer 110 and the converted integer matrix data received from the data converter 200. The PEs 310 may each include an integer multiplier and an adder to perform multiplication between integer matrix data. For example, the PE 310 is a two's complement integer operator, and may perform general matrix multiplication (GEMM) being arranges in the form of a systolic array. Because the operator 300 based on an integer operator corresponds to the conventional art, a detailed description thereof is omitted.

A detailed operation of the data converter 200, which is a main feature of the present disclosure, is described below.

First, an operation of the pre-aligner 210 included in the data converter 200 is described.

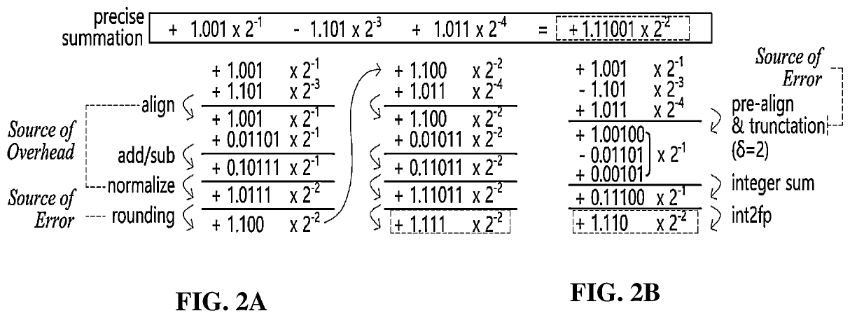

FIG. 2 illustrates diagrams of a pre-alignment process of floating-point numbers according to an embodiment of the present disclosure.

First, as a standard method for expressing floating-point numbers, the floating-point numbers are expressed by using bits representing a sign of a number, bits representing an exponent, and bits representing a mantissa (fraction, significant, mantissa). However, due to characteristics of a floating-point method, mantissa bits have different scales in which positions of respective bits are different from each other.

FIG. 2A illustrates an operation of three numbers expressed as floating-point numbers. A state is illustrated in which subtraction is first performed between the first number and the second number, and then the third number is added to a result of the subtraction. To this end, alignment is performed based on the maximum exponent of the first number and the second number, and then an operation is performed, and normalization, rounding, and so on are performed. In addition, alignment is performed based on the operation result and the maximum exponent of the third number, and then an operation is performed, and normalization and rounding are performed.

In contrast to this, the present disclosure uses a method of pre-alignment all the numbers to be operated before performing the operation, as illustrated in FIG. 2B. That is, the maximum exponent is found among the numbers to be operated, alignment is performed to match scales of respective numbers based on the maximum exponent, and then all operations are performed. In this way, when all numbers are pre-aligned, integer-type operations may be performed only for the mantissas.

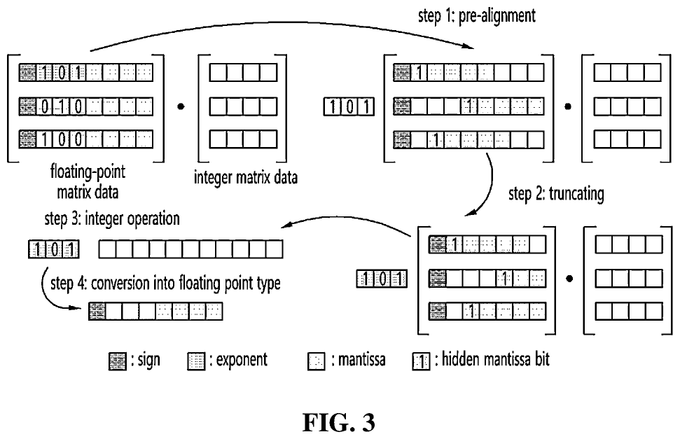

Referring to FIG. 3, pre-alignment is first performed on multiple floating point matrix data (step 1). That is, each mantissa is aligned based on the maximum exponent 101 (in FIG. 3) among multiple floating-point values. In this case, a mantissa of each floating-point is moved by a difference between the maximum exponent value and the exponent value of each floating-point value. For example, a mantissa of a floating point of which exponent is less than the maximum exponent is moved to the right. In addition, values of the mantissa moved to the right for each piece of data may be recorded and used.

Next, a preset number of high-order bits is extracted from among mantissa for which pre-alignment is completed, and only some bits are extracted, with the rest being truncated and discarded (step 2). For example, assuming that a bit resolution of integer data is Pw and a resolution of the floating point mantissa is P, by further adding spare bits (2 bits), a sign bit, and a hidden bit, only P+Pw+4 bits may be extracted from an high-order of the pre-aligned mantissa, and the remaining bits may be discarded, and thereby, only the main bits may be extracted.

Next, a common maximum exponent is excluded from the floating point for which the processing of step 2 is completed, and multiplication based on an integer value is performed on the remaining values and integer matrix data (step 3), and then an operation result is converted into a floating point number by reapplying the sign and maximum exponent.

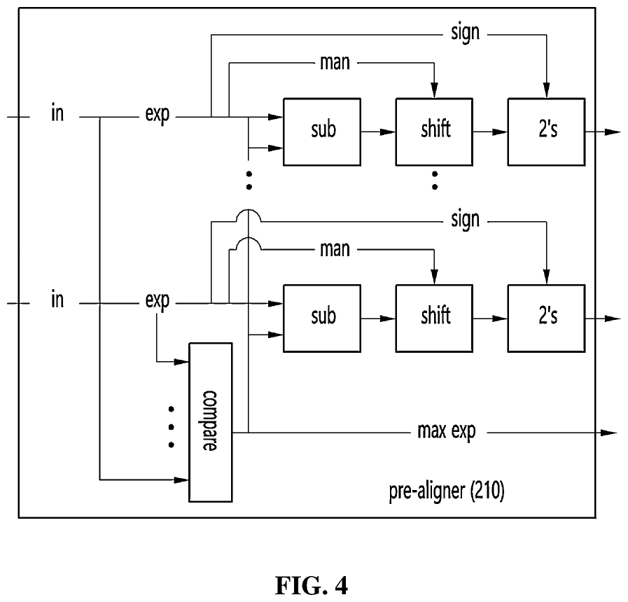

FIG. 4 illustrates a logic of a pre-aligner according to an embodiment of the present disclosure.

For the pre-alignment of floating-point numbers discussed above, an exponent exp, a mantissa man, and a sign of the floating-point value are all decomposed, and respective exponents are first compared with each other, and then the maximum exponent max exp is calculated.

Then, a difference sub between the maximum exponent max exp and a value of the exponent exp of each floating-point value is calculated, and an operation of shifting the mantissa of each floating-point value by the difference is performed. Finally, the sign is converted into a two's complement type and applied.

Next, an operation of the chunk allocator 220 included in the data converter 200 is described.

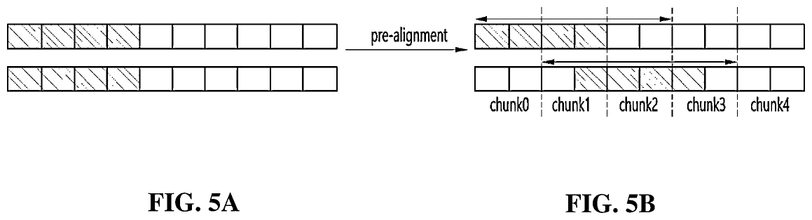

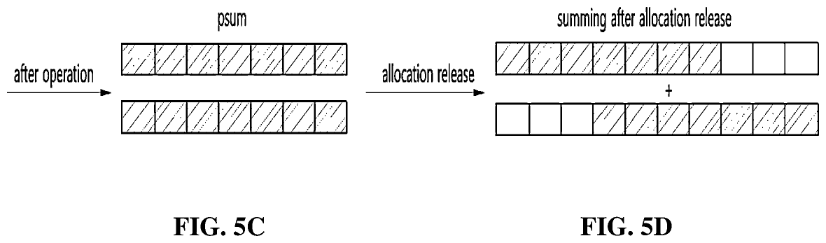

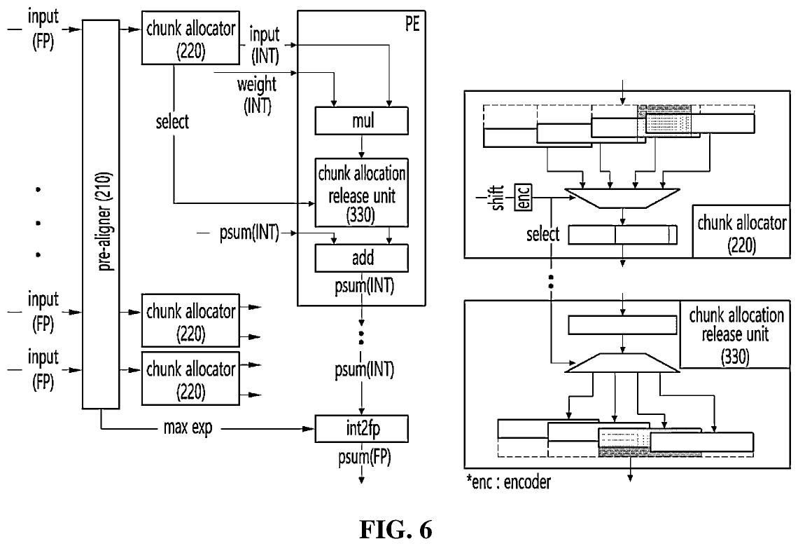

FIG. 5 illustrates diagrams of operations of the chunk allocator 220 according to an embodiment of the present disclosure, and FIG. 6 illustrates a logic of the chunk allocator 220 according to an embodiment of the present disclosure.

In order to maximize efficiency of the operation accelerator according to the present disclosure, an operation is performed based on a significant digit among the pre-aligned mantissas through the pre-aligner 210. When extracting the preset number of high-order bits during the pre-alignment process, only P+Pw+4 bits may be extracted, and accordingly, the resolution of a pre-aligned mantissa becomes P+Pw+4. However, because the resolution of a mantissa of an input floating point is lower than this, a significant number among these may be limited. In particular, because date increases by the amount of additional spare bits (Pw+2) added in the truncation step of the pre-aligner 210, the present disclosure reduces the number of bits required to express the pre-aligned mantissa by using a chunk including the significant digit among the pre-aligned mantissas and position information of the corresponding chunk. Therethrough, the number of registers used in the operation accelerator is reduced, and the size of a multiplier mul used for multiplication between the pre-aligned mantissa and an integer in each PE 310 may also be reduced.

First, as illustrated in FIG. 5A, when there are two different floating point values, pre-alignment is performed as described above. For reference, it is assumed that the size of each chunk is 2, a valid data bit width is 4, and a bit width of the pre-aligned mantissa is 10. In addition, hatched portions indicate positions of the valid data.

Next, when pre-alignment is performed as illustrated in FIG. 5B, a mantissa is moved for each floating point according to a difference between a maximum exponent value and an exponent value of each floating point value. In this case, it can be seen that numbers in the first column indicate that a mantissa is not moved and the valid data representing meaningful data is located across some chunks chunk0 and chunk1. In addition, it can be seen that numbers in the second column indicate that a mantissa is moved to the right by 3 and the valid data is located across some chunks chunk1, chunk2, and chunk3. Accordingly, the present disclosure intends to transfer valid data among mantissas of the floating-point number to the operator 300, in addition to the floating-point truncation step discussed above. To this end, information on multiple consecutive chunks where valid data is located is transferred to the operator 300. In the first column, valid data is located only in some chunks chunk0 and chunk1, but another chunk chunk2 are also transferred to match bit widths. That is, the preset number of chunks are transferred for each floating point mantissa, and positions of respective chunks may be different from each other for each floating-point mantissa. Meanwhile, the position of each chunk where valid data is located may be set based on the value obtained by moving a mantissa of each floating-point in the previous pre-alignment step. As in the second column, when the mantissa of the floating-point mantissa moves by 3, a chunk to be transferred may be set based thereon.

Next, as illustrated in FIG. 5C, multiplication between a floating-point mantissa and an integer is performed by the operator 300 based on valid data, and a partial sum psum obtained by performing multiplication for each PE 310 may be output.

Next, as illustrated in FIG. 5D, before accumulating and summing respective partial sums, a process of restoring the scale to the original position is performed for a result of each multiplication. That is, a process of releasing the chunk allocation set in the previous step is performed. To this end, chunk allocation release is performed by using the position information of the chunk including the valid data determined in the chunk allocation process of FIG. 5B. Thereafter, values obtained by releasing the chunk allocation are accumulated and summed.

Referring to FIG. 6, the pre-aligner 210 outputs a pre-aligned mantissa for multiple input floating points. In addition, each chunk allocator 220 determines a chunk including valid data among the pre-aligned mantissas and a position of a corresponding chunk and transfers the determined data to the operator 300. In particular, a position select of the chunk including valid data is transferred to a chunk allocation release unit 330 of the operator 300 to be used to release the chunk allocation for a result of each multiplication.

Next, an operation of the data setting unit 230 included in the data converter 200 is described.

The data setting unit 230 adds a delay to each row in consideration of a systolic array structure that the operator 300 has. That is, the operator 300 of the systolic array structure performs multiplication on an M*N matrix, and because the data input to each row or column is delayed by one cycle for each row or column, and by considering this, the data setting unit 230 sets the data with a delay of 1 cycle for each row and outputs the data. For example, compared to the data placed in the first row, the data placed in the second row is transferred to the operator 300 with a delay of 1 cycle.

A summing unit 460 sums the data transmitted to the operator 300 by the data setting unit 230 and transfers the data to the reformatting unit 410. As described above, the data setting unit 230 delays data by 1 cycle for each row or column and transfers the delayed data, and accordingly, in consideration of this, the data may be summed.

Next, the reformatting unit 410 that post-processes an operation result output by the operator 300, the inverse converter 420, the summing unit 430, the summing buffer 440, and the vector unit 450 are described.

The reformatting unit 410 converts output by the operator 300 to have the same result as a result calculated by using a symmetric format integer matrix data that does not include 0.

In the present disclosure, as described above, a truncation process is performed to extract only the preset number of high-order bits after performing pre-alignment on the floating point data. In this way, while multiplying the truncated floating point mantissa by integer data, when the integer data includes 0, an effect of the truncated mantissa on the operation may not be predicted. Accordingly, this may be solved by using integer data (0 less format) that does not include 0, rather than a value of the usual two's complement format. For example, a weight is expressed as integer data, and the weights may be expressed as integer data that does not include 0. However, it is difficult for the operator 300 to process integer data that does not include 0, and accordingly, the integer data is converted into a two's complement form and input to the operator 300. In this way, an operation of converting integer data that does not include 0 into a two's complement form may be processed in an offline form. In addition, because a value output by the operator 300 is integer matrix data calculated by using two's complement form weight matrix, the reformatting unit 410 performs an operation of converting an output value of the operator 300 into a value identical to a result calculated by using a symmetric format that does not include 0, which is the original expression form of a weight.

For details of the reformatting process, the symmetric format that does not include 0 to be used in the present disclosure has an interval of 2 between adjacent integers and has a symmetrical representation based on 0, and accordingly, a 2-bit integer includes −3, −1, 1, and 3. A corresponding integer value W′ may have a relationship, such as Equation 1, in relation to an integer W in a two's complement format.

$$W ’ = 2 W + 1 \qquad Equation 1$$

Therefore, assuming that an input floating point is Y, Equation 1 may be represented as YW′=2WY+Y. Therefore, even when an operation is performed by using the operator 300 that performs the operation on an integer in the usual two's complement format according to the present disclosure, a result based on a symmetric format that does not include 0 may be provided through a simple reformatting process. That is, the reformatting unit 410 may perform reformatting through a simple post-processing of multiplying a multiplication result of the operator 300 by 2 and adding an input floating point data thereto.

The inverse converter 420 converts the integer data output from the operator 300 into a floating point format.

Referring again to FIGS. 2 and 3 described above, the maximum exponent among the numbers to be operated is found, pre-alignment is performed to match scales of respective numbers based on the maximum exponent, and then all operations are performed. The inverse converter 420 performs inverse conversion according to the floating-point format by combining the maximum index found in the pre-alignment step with the integer operation result of the operator 300.

The summing unit 430 sums the floating-point format values output through the inverse converter 420 and outputs an accumulation operation result.

The summing buffer 440 may temporarily store the accumulation operation result of the summing unit 430 or temporarily store the partial sum psum calculated by each PE 310 during the operation process of the operator 300.

The vector unit 450 transfers the accumulated operation result received from the summation buffer 440 to the second buffer 120. In addition, the vector unit 450 may perform a single instruction multiple data (SIMD) operation, for example, an operation in the form of a*x+b to perform a dequantization operation. In this way, the converted final result is transferred from the second buffer 120 to the memory 20.

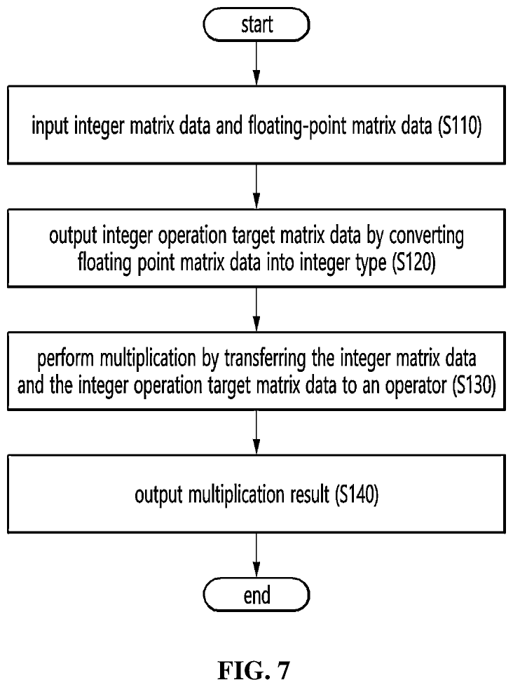

FIG. 7 is a flowchart illustrating an operation method according to an embodiment of the present disclosure.

First, each of integer matrix data and floating point matrix data is input (S110). In addition, the integer matrix data may be stored in the first buffer 110, and the floating point matrix data may be stored in the second buffer 120. In this case, the integer matrix data may represent a weight, and the floating point matrix data may represent an activation value.

Next, the floating point matrix data is converted into an integer type, and integer operation target matrix data is output (S120). More specifically, the pre-aligner 210 included in the data converter 200 finds a maximum exponent among multiple floating point values included in the floating point matrix data, and performs pre-alignment to move a mantissa of each floating point by a difference between the maximum exponent value and the exponent value of each floating point value. Then, the integer operation target matrix data is generated based on mantissas of the preset number of high-order bits extracted from the mantissas of respective pre-aligned floating-point values. In this case, when a bit resolution of the integer matrix data is Pw and a floating point mantissa resolution is P, (Pw+P+4) high-order bits may be extracted from the mantissas of the respective pre-aligned floating point values.

Meanwhile, a step of transferring information on a chunk including valid data to the operator 300 through the chunk allocator 220 to perform an operation based on the valid data may be further performed.

Next, the integer matrix data and the integer operation target matrix data are transferred to the operator 300 to perform multiplication (S130). An integer operation is performed by using each PE 310 included in the operator 300, and a final output is determined based on a sum of the integer operation.

Meanwhile, when chunk allocation for the valid data is performed in the previous step S120, the operator 300 performs an operation of releasing the chunk allocation by using position information of a chunk including the valid data.

In addition, a reformatting step, in which integer data for an operation result of the operator 300, calculated using a two's complement weight matrix including 0, is converted into integer data equivalent to that obtained using a symmetric weight matrix that does not include 0, may be further performed. The reformatting step may be performed by multiplying a result of the operator 300 by 2 and adding input floating-point data of the floating point matrix data to a result of the multiplication.

Next, a step of inversely converting an operation result of the operator 300 into a floating-point by applying an exponent and sign of each floating-point value may be further performed.

After this process is performed, a final multiplication result is output (S140). The multiplication result may be temporarily stored in the second buffer 120 and then output to the memory 20 or so on.

A method according to an embodiment of the present disclosure may be performed in the form of a recording medium including instructions executable by a computer, such as a program module executed by a computer. A computer readable medium may be any available medium that may be accessed by a computer and includes both volatile and nonvolatile media, removable and non-removable media. Also, the computer readable medium may include a computer storage medium. A computer storage medium includes both volatile and nonvolatile media and removable and non-removable media implemented by any method or technology for storing information, such as computer readable instructions, data structures, program modules or other data.

In addition, although the method and system of the present disclosure are described with respect to specific embodiments, some or all of components or operations thereof may be implemented by using a computer system having a general-purpose hardware architecture.

The above description of the present disclosure is intended to be illustrative, and those skilled in the art will appreciate that the present disclosure may be readily modified in other specific forms without changing the technical idea or essential characteristics of the present disclosure. Therefore, the embodiments described above should be understood as illustrative in all respects and not limiting. For example, each component described in a single type may be implemented in a distributed manner, and likewise, components described in a distributed manner may be implemented in a combined form.

The scope of the present application is indicated by the claims described below rather than the detailed description above, and all changes or modified forms derived from the meaning, scope of the claims, and their equivalent concepts should be interpreted as being included in the scope of the present application.

What is claimed is:

1. An operation accelerator that performs an operation between a floating point matrix and an integer matrix, the operation accelerator comprising:
a first buffer storing integer matrix data;
a second buffer storing floating point matrix data;
a data converter configured to convert the floating point matrix data into an integer; and
an operator configured to perform multiplication on the integer matrix data and integer operation target matrix data output from the data converter,
wherein the data converter includes a pre-aligner configured to find a maximum exponent value among multiple floating point values included in the floating point matrix data, perform pre-alignment for moving a mantissa of each of floating points by a difference between the maximum exponent value and an exponent value of each of the multiple floating point values, and generate the integer operation target matrix data based on mantissas of a preset number of high-order bits extracted from among mantissas of pre-aligned floating point values.

2. The operation accelerator of claim 1, wherein,
when a bit resolution of the integer matrix data is Pw and a mantissa resolution of the floating-point value is P, the pre-aligner generates the integer operation target matrix data based on mantissas of Pw+P+4 high-order bits extracted from among mantissas of the pre-aligned floating-point values.

3. The operation accelerator of claim 1, wherein
the data converter includes a chunk allocator configured to transfer information on a chunk including valid data extracted from the mantissas of the preset number of high-order bits extracted from among the mantissas of the pre-aligned floating point values to the operator such that an operation is performed based on the valid data, and
the operator includes a chunk allocation release unit configured to release chunk allocation by using position information of the chunk including the valid data.

4. The operation accelerator of claim 1, further comprising:
a reformatting unit configured to convert an operation result of the operator into a value in the same manner as a result obtained by calculating integer data in two's complement form including 0 by using a symmetric format that does not include 0,
wherein the reformatting unit multiplies the operation result of the operator by 2 and adds input floating-point data of the floating point matrix data to a result of multiplication.

5. The operation accelerator of claim 1, wherein
an operation result of the operator is inversely converted into a floating-point by applying an exponent and a sign of each of the multiple floating-point values to the operation result of the operator.

6. The operation accelerator of claim 1, wherein
The second buffer temporarily stores an operation result of the operator.

7. An operation method for processing an operation between a floating-point matrix and an integer matrix by using an operation accelerator, the operation method comprising:
inputting integer matrix data and floating point matrix data respectively;
outputting integer operation target matrix data by converting the floating point matrix data into integers; and
performing multiplication by transferring the integer matrix data and the integer operation target matrix data to an operator,
wherein the outputting of the integer operation target matrix data includes finding a maximum exponent value among multiple floating point values included in the floating point matrix data, performing pre-alignment for moving a mantissa of each of floating points by a difference between the maximum exponent value and an exponent value of each of the multiple floating point values, and generating the integer operation target matrix data based on mantissas of a preset number of high-order bits extracted from among mantissas of pre-aligned floating point values.

8. The operation method of claim 7, wherein,
in the outputting of the integer operation target matrix data, when a bit resolution of the integer matrix data is Pw and a mantissa resolution of the floating-point value is P, the integer operation target matrix data is generated based on mantissas of Pw+P+4 high-order bits extracted from among mantissas of the pre-aligned floating-point values.

9. The operation method of claim 7, wherein
the outputting of the integer operation target matrix data further includes transferring information on a chunk including valid data extracted from the mantissas of the preset number of high-order bits extracted from among the mantissas of the pre-aligned floating point values to the operator such that an operation is performed based on the valid data, and
in the performing of the multiplication, the operator releases chunk allocation by using position information of the chunk including the valid data.

10. The operation method of claim 7, further comprising:
reformatting of converting an operation result of the operator into a value in the same manner as a result obtained by calculating integer data in two's complement form including 0 by using a symmetric format that does not include 0, and
in the reformatting, the operation result of the operator is multiplied by 2 and input floating-point data of the floating point matrix data is added to a result of multiplication.

11. The operation method of claim 8, further comprising:
inversely converting an operation result of the operator into a floating-point by applying an exponent and a sign of each of the multiple floating-point values to the operation result of the operator.

12. A non-transitory recording medium in which a computer program for executing the operation method according to claim 7 is recorded.
